(19) United States
(12) Patent Application Publication
(10) Pub. No.: US 2024/0421018 A1
(43) Pub. Date: Dec. 19, 2024

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventor: Kazuma KAWAMURA, Matsumoto-city (JP)

(73) Assignee: FUJI ELECTRIC CO., LTD., Kawasaki-shi (JP)

(21) Appl. No.: 18/646,424

(22) Filed: Apr. 25, 2024

(30) Foreign Application Priority Data
Jun. 14, 2023 (JP) 2023-097720

(51) Int. Cl. H01L 23/31; H01L 23/00; H01L 23/12; H01L 25/065

(52) U.S. Cl. CPC H01L 23/3142; H01L 23/12; H01L 24/16; H01L 24/48; H01L 24/73; H01L 25/0655; H01L 2224/16145; H01L 2224/16225; H01L 2224/48137; H01L 2224/48155; H01L 2224/73257; H01L 2924/01029; H01L 2924/0665; H01L 2924/13055; H01L 2924/182; H01L 2924/183

(57) ABSTRACT

A semiconductor device, including: a stacked substrate; a plurality of semiconductor chips provided on the stacked substrate; an external output terminal; a circuit board configured to electrically connect the plurality semiconductor chips, and to electrically connect the plurality of semiconductor chips to the external output terminal, the circuit board having a first surface and a second surface opposite to each other, the second surface facing the stacked substrate; a sealing resin sealing the stacked substrate and the circuit board; and a plurality of flow velocity control pins attached to the circuit board, at the first surface of the circuit board.

### CROSS REFERENCE TO RELATED APPLICATIONS

This application is based upon and claims the benefit of priority of the prior Japanese Patent Application No. 2023-097720, filed on Jun. 14, 2023, the entire contents of which are incorporated herein by reference.

### BACKGROUND OF THE INVENTION

### 1. Field of the Invention

Embodiments of the invention relate to a semiconductor device and a method of manufacturing a semiconductor device.

### 2. Description of the Related Art

Conventionally, a semiconductor device having a flow pressure adjusting member capable of moving upstream and downstream in a channel having a larger cross-sectional area among two channels is known (for example, refer to Japanese Laid-Open Patent Publication No. H7-74193).

### SUMMARY OF THE INVENTION

According to an embodiment of the present invention, a semiconductor device, including: a stacked substrate; a plurality of semiconductor chips provided on the stacked substrate; an external output terminal; a circuit board configured to electrically connect the plurality semiconductor chips, and to electrically connect the plurality of semiconductor chips to the external output terminal, the circuit board having a first surface and a second surface opposite to each other, the second surface facing the stacked substrate; a sealing resin sealing the stacked substrate and the circuit board; and a plurality of flow velocity control pins attached to the circuit board, at the first surface of the circuit board.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-section view depicting a structure of a semiconductor device according to a first embodiment.

FIG. 2 is a plan view depicting the structure of the semiconductor device according to the first embodiment, when viewed from a circuit board.

FIG. 3 is a side view of the structure of the semiconductor device according to the first embodiment.

FIG. 4 is a cross-sectional view depicting sealing resin injection in a method of manufacturing the semiconductor device according to the first embodiment.

FIG. 5 is a cross-sectional view depicting the sealing resin injection in the method of manufacturing the semiconductor device according to the first embodiment.

FIG. 6 is a cross-sectional view depicting the sealing resin injection in the method of manufacturing the semiconductor device according to the first embodiment.

FIG. 7 is a cross-sectional view depicting the sealing resin injection in the method of manufacturing the semiconductor device according to the first embodiment.

FIG. 8 is a cross-sectional view depicting the sealing resin injection in the method of manufacturing the semiconductor device according to the first embodiment.

FIG. 9 is a cross-sectional view depicting a structure of the semiconductor device according to a second embodiment.

FIG. 10 is a plan view depicting the structure of the semiconductor device according to the second embodiment.

FIG. 11 is a cross-sectional view depicting alleviation of stress during manufacture of the semiconductor device according to the second embodiment.

FIG. 12 is a cross-sectional view depicting the alleviation of stress during manufacture of the semiconductor device according to the second embodiment.

FIG. 13 is a cross-sectional view depicting a method of evaluating voids in an example.

FIG. 14 is a cross-sectional view depicting the method of evaluating voids in the example.

FIG. 15 is a cross-sectional view depicting the method of evaluating voids in the example.

FIG. 16 is a cross-sectional view depicting evaluation of voids behind flow velocity control pins in the example.

FIG. 17 is a cross-sectional view depicting a warped surface plate of a tightening test in the example.

FIG. 18 is a cross-sectional view depicting warpage of a module in the example.

FIG. 19 is a cross-sectional view depicting the tightening test of a semiconductor device in the example.

FIG. 20 is a cross-sectional view depicting shapes of the flow velocity control pins of semiconductor devices of the example.

FIG. 21 is a cross-sectional view depicting a sealing resin injection in a method of manufacturing a conventional semiconductor device.

FIG. 22 is a cross-sectional view depicting the sealing resin injection in the method of manufacturing the conventional semiconductor device.

FIG. 23 is a cross-sectional view depicting the sealing resin injection in the method of manufacturing the conventional semiconductor device.

FIG. 24 is a cross-sectional view depicting the sealing resin injection in the method of manufacturing the conventional semiconductor device.

FIG. 25 is a cross-sectional view depicting the sealing resin injection in the method of manufacturing the conventional semiconductor device.

FIG. 26 is a cross-sectional view depicting generation of warpage in the conventional semiconductor device.

FIG. 27 is a cross-sectional view depicting an occurrence of stress during manufacture of the conventional semiconductor device.

FIG. 28 is a cross-sectional view depicting occurrence of resin cracking during the manufacture of the conventional semiconductor device.

### DETAILED DESCRIPTION OF THE INVENTION

Embodiments of a semiconductor device and a method of manufacturing a semiconductor device according to the present invention are described in detail with reference to the accompanying drawings. Nonetheless, the present invention is not limited by the embodiments described below.

First, problems associated with the conventional techniques are discussed. In the conventional semiconductor device, when the semiconductor device is sealed by transfer molding, bubbles (voids) are generated due to the trapping of air at a point where surfaces of flowing resin converge and a problem arises in that the semiconductor device becomes defective.

The conventional semiconductor device has a structure in which a semiconductor chip 101 and aluminum wiring mounted on a stacked substrate 105, lead frame wiring, etc. are sealed with a sealing resin 110 by the transfer molding. Especially in the last few years, with increases in the density of mounted semiconductor devices, modules with a stacked structure in which another circuit board 109 is provided at an upper portion of the stacked substrate 105 and a portion of the wiring is transferred thereto are increasing.

Transfer molding is a method of injecting the sealing resin 110 in a molten liquid state into a mold cavity 118. FIGS. 21, 22, 23, 24, and 25 are cross-sectional views depicting sealing resin injection in a method of manufacturing the conventional semiconductor device. First, a module is created in which the circuit board 109 is provided on the stacked substrate 105 to which the semiconductor chip 101 is mounted. As depicted in FIG. 21, the module is placed face-down in the mold cavity 11. The sealing resin 110 flows in a direction from a gate 120 to an air vent 121. The air vent 121 is provided to allow air inside the mold cavity to escape; and to facilitate the function of the air vent 121, it is preferable for the sealing resin 110 to converge in a region S1.

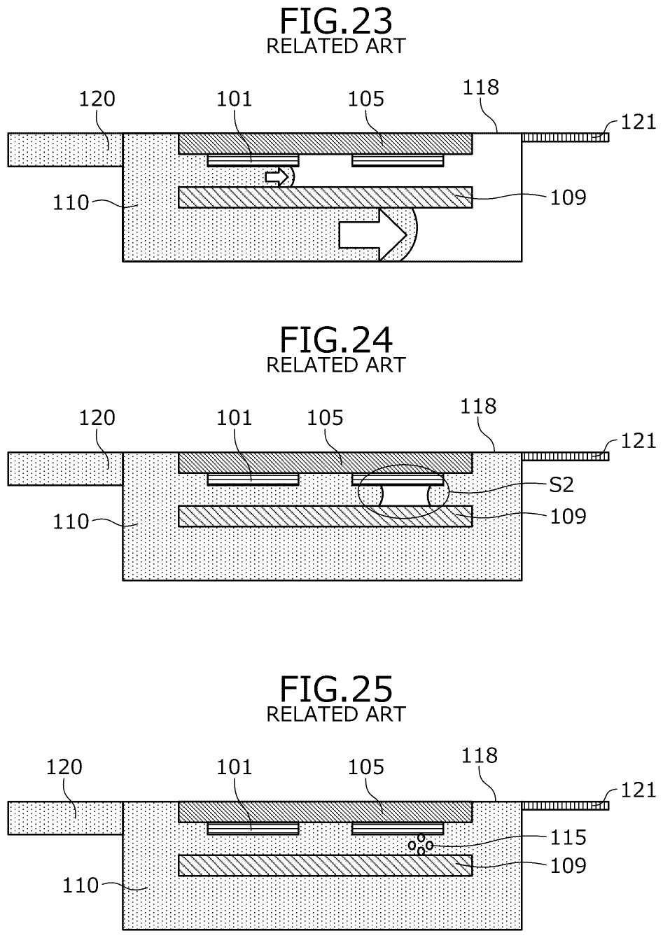

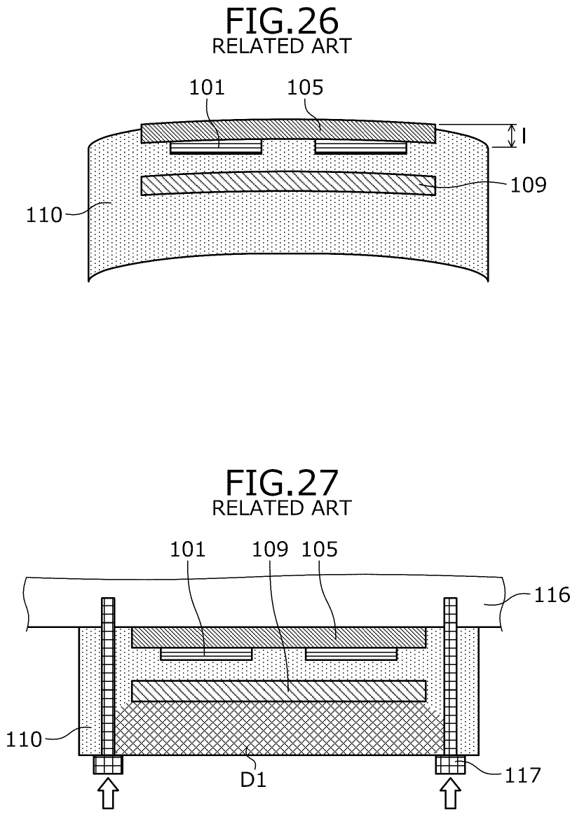

Next, as depicted in FIGS. 22 and 23, the sealing resin 110 is injected into the mold cavity 118 in the direction indicated by the arrows in the drawings. The sealing resin 110 is a highly viscous fluid and thus, a smaller amount flows in a gap between the stacked substrate 105 and the circuit board 109 as compared to an amount flowing between the circuit board 109 and the mold cavity 118, whereby a difference in the flow velocities above and below the circuit board 109 occurs. Thus, as depicted in FIG. 24, in some instances, confluence of the sealing resin 110 may not be in the region S1. In such an instance, confluence of the sealing resin 110 is in a region S2 apart from the air vent 121, trapping air unable to escape through the air vent 121 and generating a void 115. As depicted in FIG. 25, when the void 115 occurs near the semiconductor chip 101, a problem arises in that the semiconductor device becomes defective due to the void 115. In particular, strength and insulation are affected.

With the conventional techniques, problems arise in that controlling the flow velocity of the resin is difficult and in particular, with the recently increasing number of modules having a stacked structure, flow to a gap between two substrates is necessary while the difficulty in controlling flow velocity is high.

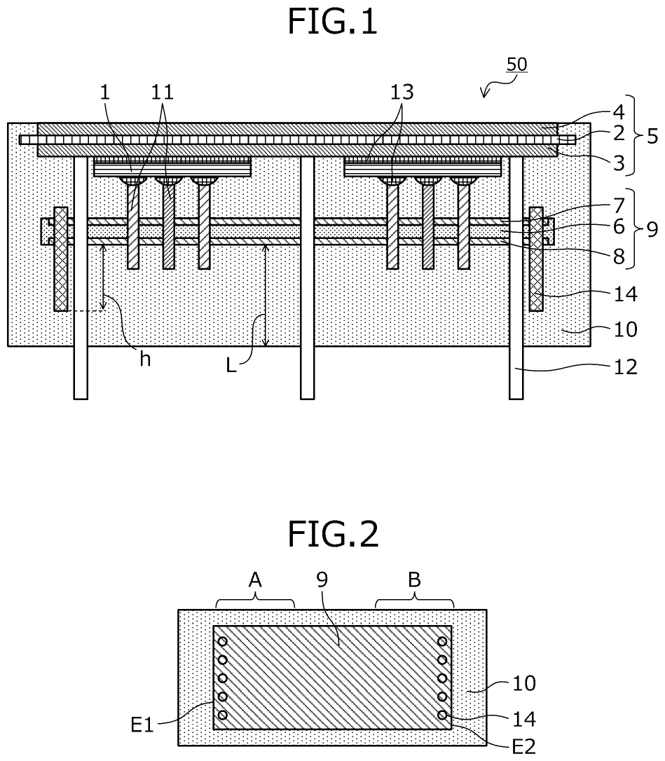

A semiconductor device that, according to the first embodiment, solves the problems above is described. FIG. 1 is a cross-section view depicting a structure of the semiconductor device according to the first embodiment. A semiconductor device 50 depicted in FIG. 1 represents a power semiconductor module. The semiconductor device 50 has a stacked substrate 5 on which power semiconductor chips 1 are mounted, the stacked substrate 5 having a structure in which a first conductive substrate 3 and a second conductive substrate 4 are stacked on a first insulated substrate 2; the semiconductor device 50 further has a circuit board 9 with a stacked structure in which a third conductive substrate 7 and a fourth conductive substrate 8 are stacked on a second insulated substrate 6; the power semiconductor chips 1 are bonded on the first conductive substrate 3 by solder 13. In the present description, while the circuit board 9 is disposed above (in FIG. 1, below) the power semiconductor chips 1, the circuit board 9 may be disposed below the power semiconductor chips 1 with the stacked substrate 5 intervening therebetween. Further, when the semiconductor device 50 depicted in FIG. 1 is used after removal from the mold after the transfer molding, the semiconductor device 50 may be inverted and connected to a cooling device (not depicted), wiring (not depicted), etc. Further, in the present description, “above” the semiconductor device 50 and/or the power semiconductor chips 1 is depicted as being “below” in FIG. 1 while “below” the semiconductor device 50 and/or the power semiconductor chips 1 is depicted as being “above” in FIG. 1.

The first conductive substrate 3 and the second conductive substrate 4 are, for example, copper (Cu) plates, while the first insulated substrate 2 is an insulated ceramic substrate. Further, the third conductive substrate 7 and the fourth conductive substrate 8 are, for example, metal patterns while the second insulated substrate is an epoxy substrate. The circuit board 9 has wiring between the power semiconductor chips 1 and between the power semiconductor chips 1 and external output terminals 12. Via holes are opened in the circuit board 9, wiring pins 11 containing nickel (Ni) for wiring are inserted into the via holes using a pin-terminal inserting jig, and the wiring pins 11 and the power semiconductor chips 1 are bonded by the solder 13 and thereby wired. Transfer sealing by a mold temperature of 175 degrees C. is performed using a sealing resin 10, for example, an epoxy resin with a Tg (glass transition state) of 200 degrees.

The semiconductor device 50 according to the first embodiment is not limited to a pin structure in which the stacked substrate 5 and the circuit board 9 are wired by the wiring pins 11 and provided the structure has the two layers (the stacked substrate 5 and the circuit board 9), an effect of controlling the path of the flow of the resin may be obtained. For example, instead of the wiring pins 11 electrically connecting the stacked substrate 5 and the circuit board 9, wiring members, a lead frame structure implementing wiring by a Cu plate or block may be used.

The power semiconductor chips 1 may be, for example, power chips such as diodes or insulated gate bipolar transistors (IGBTs) or silicon (Si) devices or wide band gap semiconductor devices such as silicon carbide (SiC) devices, gallium nitride (GaN) devices, diamond devices, zinc oxide (ZnO) devices, etc. Further, a combination of these devices may be used. For example, a hybrid module using a Si-IGBT and a SiC-SBD may be used. The number of the stacked power semiconductor chips 1 may be one or more.

The stacked substrate 5 may be configured by the first insulated substrate 2, the first conductive substrate 3 formed at a first main surface of the first insulated substrate 2, and the second conductive substrate 4 formed at a second main surface of the first insulated substrate 2. For the first insulated substrate 2, a material with excellent electrical insulation and thermal conductivity may be used. As a material of the first insulated substrate 2, for example, Al₂O₃, AlN, SiN, etc. may be used, or a thermosetting resin such as an epoxy resin may be used. Especially in high-voltage applications, a material that achieves both electrical insulation and thermal conductivity is desirable, such as, but not limited to AlN and SiN. For the first conductive substrate 3 and the second conductive substrate 4, a metal material such as Cu or Al having excellent processability may be used. Further, to prevent rust, the first conductive substrate 3 and the second conductive substrate 4 may contain Cu or Al treated with Ni plating. As a method of disposing the first conductive substrate 3 and the second conductive substrate 4 on the first insulated substrate 2, direct copper bonding or active metal brazing may be used. Further, the power semiconductor chips 1 are bonded to the first conductive substrate 3 by a bonding material such as the solder 13 and are thereby, mounted thereto.

The sealing resin 10 for transfer molding includes a thermosetting resin and an inorganic filler contained in the thermosetting resin. The thermosetting resin is mainly composed of, for example, at least one selected from a group including an epoxy resin, a phenolic resin, and a melamine resin. Preferably, the thermosetting resin may be mainly composed of an epoxy resin. Further, as the inorganic filler, an inorganic substance with high insulation and high thermal conductivity is used. The inorganic substance is mainly composed of, for example, at least one selected from a group including aluminum oxide, aluminum nitride, silicon nitride, and boron nitride. Preferably, the inorganic filler may be mainly composed of a silicon oxide. When a silicon oxide is used, the silicon oxide also functions as a mold releasing agent. Further, high flame retardancy may be maintained without addition of, for example, halogen-based, antimony-based, or metal-hydroxide-based flame retardants. The inorganic filler is in a range of 70 vol % to 90 vol % of the total encapsulating raw material.

Shear viscosity at the time of melting of the sealing resin 10 by transfer molding is, for example, in a range of 10 Pa·s to 4000 Pa·s (shear rate 0.06 (1/s)) and preferably, may be in a range of about 100 Pa·s to 2000 Pa·s.

Furthermore, the sealing resin 10 may optionally contain a curing agent, a curing accelerator, or an additive in addition to the thermosetting resin and the inorganic filler. While the curing agent is not particularly limited provided the curing agent reacts with a thermosetting resin main agent, preferably, an epoxy resin main agent, and can be cured, use of an acid anhydride curing agent is preferable. Examples of the acid anhydride curing agent include an aromatic acid anhydride, specifically phthalic anhydride, pyromellitic dianhydride, trimellitic anhydride, or the like. Alternatively, a cyclic aliphatic anhydride, specifically, tetrahydrophthalic anhydride, methyltetrahydrophthalic anhydride, hexahydrophthalic anhydride, methylhexahydrophthalic anhydride, methyl nadic anhydride or the like, or an aliphatic anhydride, specifically, a succinic anhydride, a poly adipic anhydride, a poly sebacic anhydride, a poly azelaic anhydride or the like may be given as examples.

As the curing accelerator, imidazole or a derivative thereof, a tertiary amine, a boric acid ester, a Lewis acid, an organometallic compound, an organic acid metal salt, or the like may be suitably added. Additives include, but are not limited to, for example, flame retardants, pigments for coloring resins, plasticizers and silicone elastomers for improving crack resistance. These optional components and the amount added may be suitably determined by those skilled in the art according to specifications necessary for the semiconductor device 50 and the sealing resin 10.

FIG. 2 is a plan view depicting the structure of the semiconductor device according to the first embodiment, when viewed from the circuit board. In the first embodiment, as depicted in FIG. 2, flow velocity control pins 14 for adjusting resin confluence positions are provided in additional via holes opened in an end portion A and an end portion B of the circuit board 9. The flow velocity control pins 14 are provided in plural on a first surface (in the end portion A) opposite to a second surface facing the stacked substrate 5, near an edge E1 of the circuit board 9, the edge E1 being near a position closest to a surface where a gate 20 of a mold cavity 18 is located, and the flow velocity control pins 14 being disposed aligned in a direction orthogonal to the direction of flow of the sealing resin 10 (hereinafter, “direction of flow of the resin”). Further, the flow velocity control pins 14 may be similarly disposed in the end portion B at an edge (edge E2) at a position opposite to the edge E1. The flow velocity control pins 14 in the present invention are mounted directly to the semiconductor device 50 and thus, even after the transfer molding, the flow velocity control pins 14 continue to remain in the semiconductor device 50. FIG. 2 and other drawings are conceptual diagrams showing the flow velocity control pins 14 while the external output terminals 12 are not depicted.

Further, as a material of the flow velocity control pins 14, a resin or a metal may be used. In particular, when the flow velocity control pins 14 having an elastic modulus lower than an elastic modulus of the sealing resin 10 is used, an effect of enhancing tolerance against destruction due resin cracking may be realized by a stress relieving effect. Since the flow velocity control pins 14 have to be placed in a high-temperature mold, when the flow velocity control pins 14 contain a resin, a resin having a glass transition temperature Tg 15 degrees C. or higher than the mold temperature during the transfer molding has to be used so that the function of controlling the flow velocity is not lost by the elastic modulus decreasing due to glass transition. When the flow velocity control pins 14 contain a metal, Ni/Cu pins like the wiring pins 11 may be used. The flow velocity control pins 14 are provided in the opposite direction from the stacked substrate 5 and are substantially orthogonal the circuit board 9. In other words, the flow velocity control pins 14 are provided between the circuit board 9 and a bottom (in FIG. 4, surface on a lower side) of the mold cavity 18.

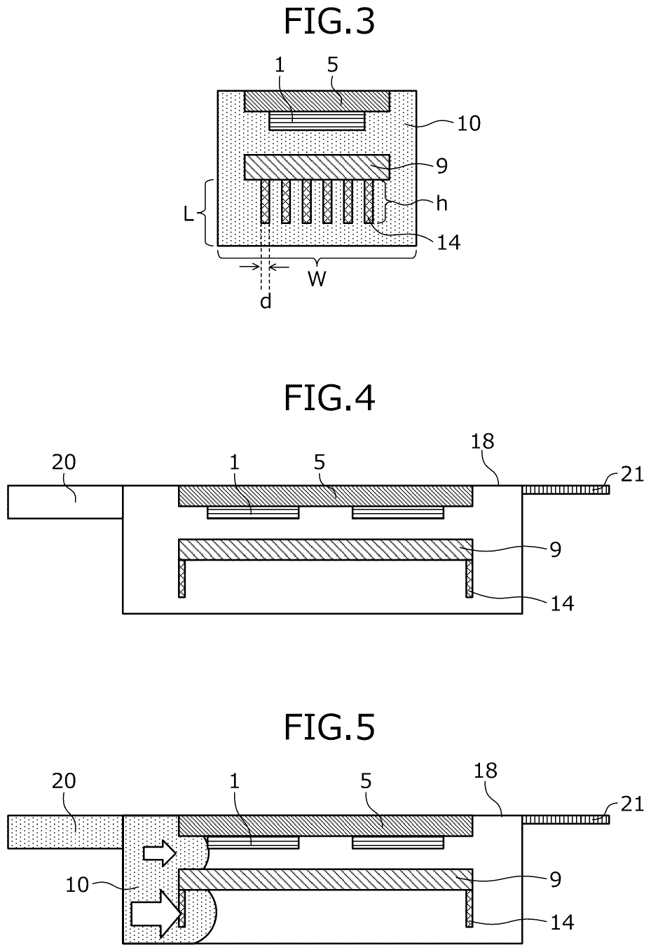

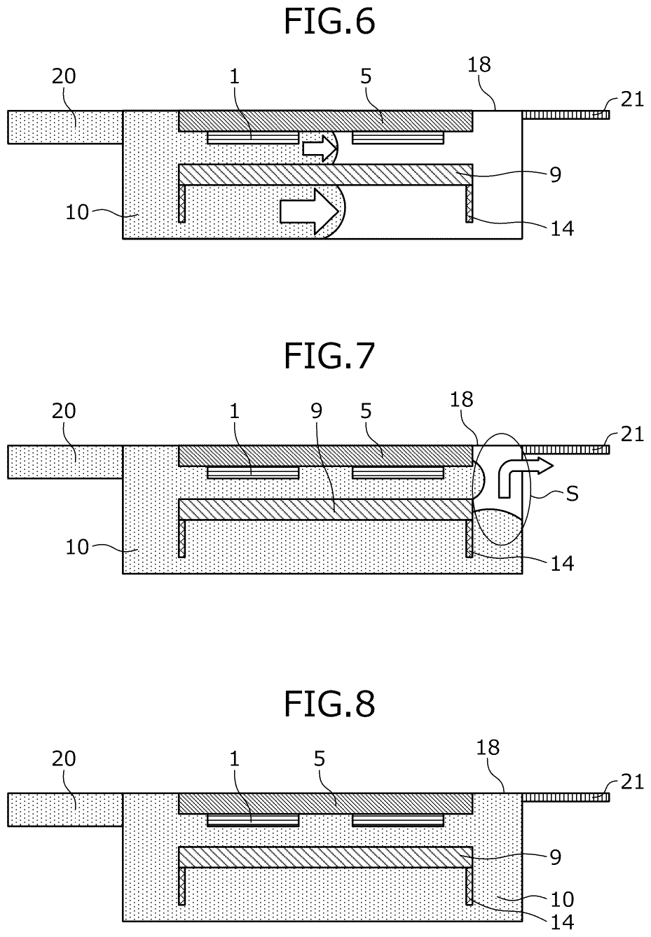

FIG. 3 is a side view of the structure of the semiconductor device according to the first embodiment. At opposite ends of the circuit board 9 are the end portion A and the end portion B, the end portion A being an end portion facing the gate 20 of the circuit board 9, more specifically, a region within a range of 30% of a length of the circuit board 9 from the edge E1 of the circuit board 9, facing the gate 20; and the end portion B being an end portion at an opposite side of the circuit board 9, from the gate 20, more specifically, a region within a range of 30% of the length of the circuit board 9 from the edge E2 of the circuit board 9 opposite to the edge E1 facing the gate 20 (refer to FIG. 2). The direction of flow of the resin is a direction from the edge E1 facing the gate 20 to the edge E2 opposite to the edge E1 facing the gate 20 (indicated by arrows in FIGS. 5 and 6). The same applies in an instance of misalignment of the gate 20 and an air vent 21 in a diagonal direction in a plan view of the mold.

In a method of manufacturing the semiconductor device according to the first embodiment, first, the power semiconductor chips 1, etc. are mounted on the stacked substrate 5 and the flow velocity control pins 14 are attached to the circuit board 9. When the flow velocity control pins 14 contain a resin, the flow velocity control pins 14 are attached to the circuit board 9 by, for example, metal patterns of the circuit board 9, an adhesive or laser welding to a glass epoxy substrate, etc. Further, the flow velocity control pins 14 may be inserted into via holes or recesses in the circuit board 9. When the flow velocity control pins 14 contain a metal, for example, attachment thereof is by soldering, insertion into recesses or via holes opened in the circuit board 9 and an adhesive may be used. In this case, preferably, from the perspective of adhesion, the adhesive may be a same type as the sealing resin 10. Next, the module in which the circuit board 9 is attached to the stacked substrate 5 by the wiring pins 11 is fabricated (the module before encapsulation). The processes up to here are referred to as a first process. FIGS. 4, 5, 6, 7, and 8 are cross-sectional views depicting sealing resin injection in the method of manufacturing the semiconductor device according to the first embodiment. In FIGS. 4 to 8, the wiring pins 11, etc. are not depicted.

Next, as depicted in FIG. 4, the module is placed in the mold cavity (mold) 18 upside down (second process). Next, as depicted in FIGS. 5 and 6, the sealing resin 10 is injected in the mold cavity 18 in the direction indicated by the arrows (the third process). The sealing resin 10 flows in a direction from the gate (injection gate) 20 to the air vent 21. The sealing resin 10 is a highly viscous fluid and thus, the amount thereof flowing in a gap between the stacked substrate 5 and the circuit board 9 is less than the amount thereof flowing between the circuit board 9 and the mold cavity 188, whereby a difference in the flow velocities above and below the circuit board 9 occurs. Nonetheless, in the first embodiment, the flow velocity control pins 14 are provided between the circuit board 9 and the mold cavity 18 (bottom). As a result, when the sealing resin 10 flows past the flow velocity control pins 14, resistance is generated by the flow velocity control pins 14, whereby the flow velocity of the sealing resin 10 decreases. As a result, the sealing resin 10 has difficulty flowing between the circuit board 9 and the mold cavity 18 and instead flows between the stacked substrate 5 and the circuit board 9 and thus, the flow velocities of the sealing resin 10 above and below the circuit board may be equalized.

Therefore, as depicted in FIG. 7, the sealing resin 10 converges in a vicinity S of the air vent 21, whereby trapped air is able to escape and as depicted in FIG. 8, the generation of voids when the sealing resin 10 is injected may be reduced. Further, the flow velocity control pins 14 are suitably arranged according to the shape of the product, whereby the resin flow velocity is controlled and, for example, confluence of the sealing resin 10 may be moved to a location with a low risk of voids occurring.

As described above, according to the first embodiment, the flow velocity control pins are disposed at the ends and are arranged so as to be orthogonal to the direction of flow of the resin and thus, when the resin passes between the flow velocity control pins, the resin is subjected to resistance from the flow velocity control pins, thereby slowing down the flow resin, enabling the location of confluence of the resin to be adjusted and thus, reducing the generation of voids or enabling the location of void generation to be moved to a location with a low risk of generating voids.

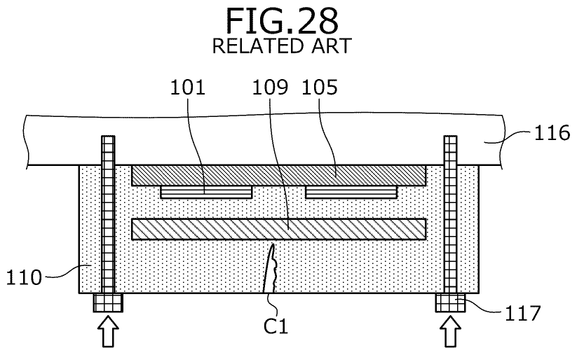

Before a second embodiment is described, first, problems associated with the conventional semiconductor device are discussed. FIG. 26 is a cross-sectional view depicting generation of warpage in the conventional semiconductor device. In the conventional semiconductor device, after the transfer molding, warpage due to curing shrinkage of the sealing resin 110 may occur. As depicted in FIG. 26, warpage having a height I occurs at an upper portion of the stacked substrate 105 and the sealing resin 110. FIG. 27 is a cross-sectional view depicting an occurrence of stress during manufacture of the conventional semiconductor device. The semiconductor device is mounted to a metal plate 116 such as a condenser and when fixed by mounting screws 117, tensile stress due to tightening of the screws is generated in a location D1. FIG. 28 is a cross-sectional view depicting occurrence of resin cracking during the manufacture of the conventional semiconductor device. When the tensile stress becomes a certain amount or greater, as depicted in FIG. 28, a problem arises in that resin cracking occurs in a location C1 and the semiconductor device fails.

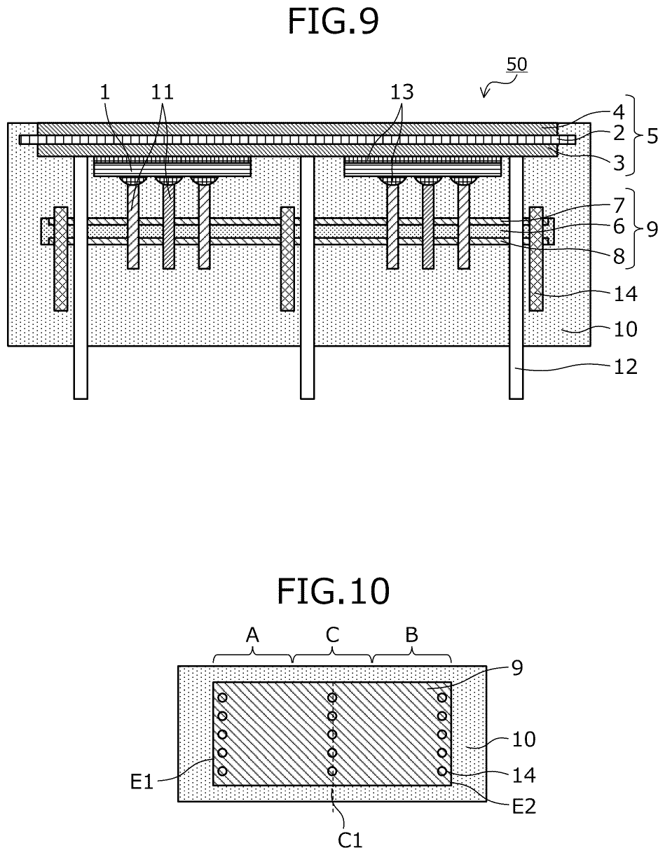

To solve the problems described above, a semiconductor device according to the second embodiment is described. FIG. 9 is a cross-sectional view depicting a structure of the semiconductor device according to the second embodiment. As depicted in FIG. 9, the semiconductor device 50 according to the second embodiment differs from the semiconductor device 50 according to the first embodiment in that the flow velocity control pins 14 are further disposed at intermediate points (intermediate region C) between the end portions A, B of the circuit board 9, arranged orthogonal to the direction of flow of the resin.

FIG. 10 is a plan view depicting the structure of the semiconductor device according to the second embodiment. The end portions A, B are the same as those in the first embodiment. The intermediate region C is a region occupying 15% of the length of the circuit board 9 from both sides of a line C1 equally dividing the circuit board 9 orthogonal to the direction of flow of the resin (the intermediate region C occupying a total of 30% of the length).

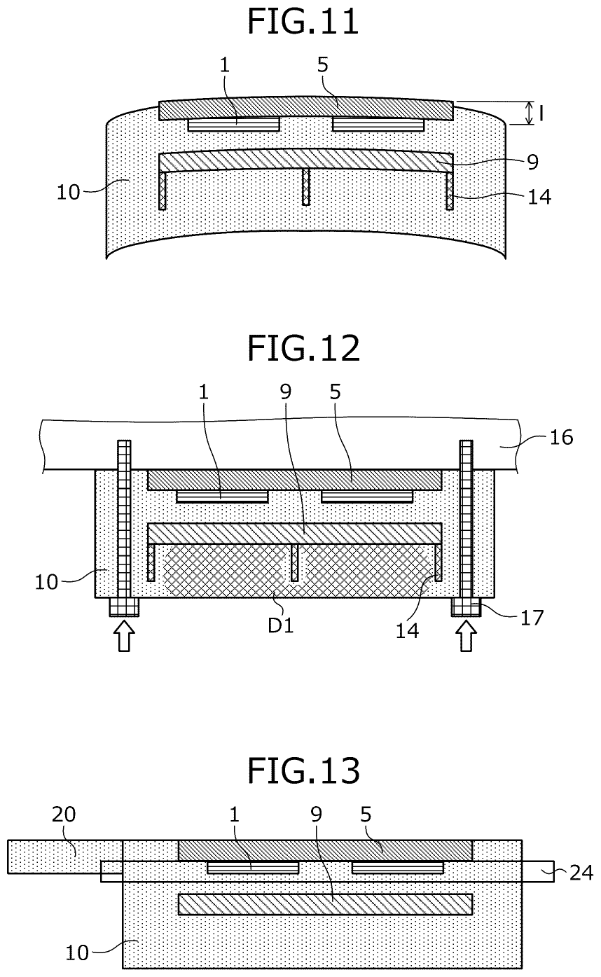

FIGS. 11 and 12 are cross-sectional views depicting alleviation of stress during manufacture of the semiconductor device according to the second embodiment. After the transfer molding, warpage of the sealing resin 10 due to curing shrinkage occurs and as depicted in FIG. 11, at the upper portion of the stacked substrate 5 and the sealing resin 10, the occurring warpage has the height I. As depicted in FIG. 12, when the semiconductor device 50 is mounted to a metal plate 16 and fixed thereto with mounting screws 17, tensile stress due to tightening of the screws is generated in a location D1. In the second embodiment, the flow velocity control pins 14 are disposed in the location D1, whereby the tensile stress is generated and thus, the flow velocity control pins 14 may alleviate the stress due to tightening of the screws, resin cracking in the location C1 is avoided, and tolerance against failure may be improved. Further, the second embodiment is presumed to also have an effect due enhancing rigidity of the power semiconductor module.

Here, in particular, for the material of the flow velocity control pins 14, a resin that stretches more than the sealing resin 10 and has an elastic modulus value lower than the elastic modulus value of the sealing resin 10 is selected, whereby stress generated in the sealing resin 10 is mitigated, destruction due resin cracking is further avoided, and tolerance against failure may be further improved. Even when a metal is used as a material of the flow velocity control pins 14 instead of a resin, the high rigidity of the metal has an effect of suppressing deformation, thereby circumventing resin cracking and enabling improvement of tolerance against destruction. When the flow velocity control pins 14 contain a metal and a resin as materials, the resin has a greater effect in terms of improving tolerance against destruction due resin cracking. Further, disposal of the flow velocity control pins 14 in the intermediate region C has a further effect of reducing voids generated in a vicinity of the power semiconductor chips 1.

As described, in the second embodiment, multiple flow velocity control pins are further provided at intermediate points between the end portions of the circuit board, whereby stress due tightening of the screws may be mitigated or rigidity may be enhanced, increasing the strength of the module against deformation, thereby preventing resin cracking and enabling enhanced tolerance against failure.

Examples of the height, shape and arrangement of the flow velocity control pins 14 in the first embodiment and the second embodiment are described hereinafter. First, a method of evaluating effects of the flow velocity control pins 14 is described. As an evaluation method, a dielectric breakdown test is performed to evaluate voids, while a reliability test and a tightening test are performed with respect to the strength of the module against deformation.

FIGS. 13, 14, and 15 are cross-sectional views depicting the method of evaluating voids in an example. Voids 15 are evaluated by performing scanning acoustic tomography (SAT) and transmission X-ray imaging with respect to a sample filled with the sealing resin 10, viewing the SAT image or X-ray image for a height (observation surface 24) at which the stacked substrate 5 and the power semiconductor chips 1 can be photographed, and evaluating locations where voids occur.

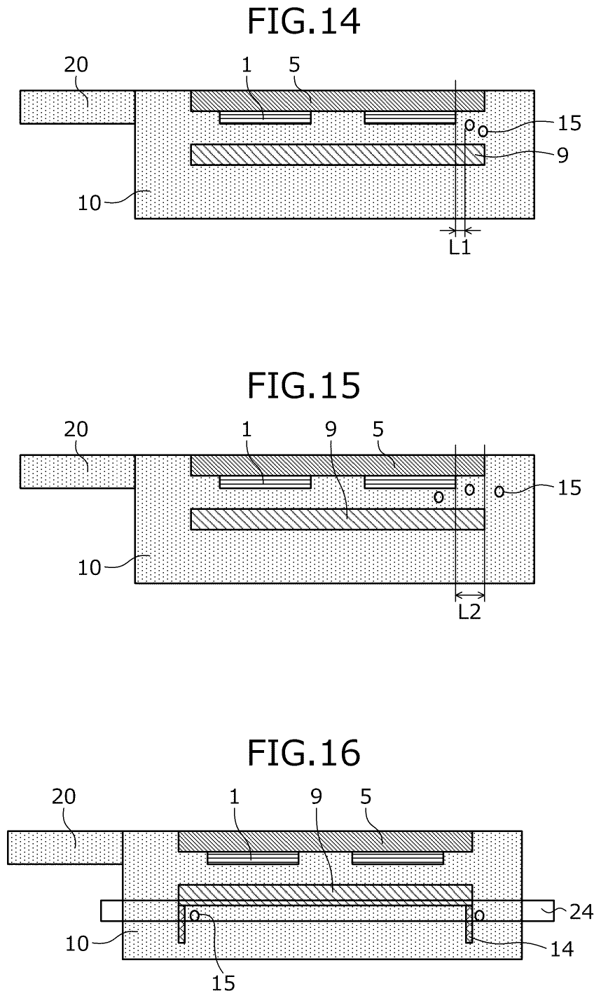

It is desirable for the voids 15 to be located as far as possible from the power semiconductor chips 1 to which high voltage is applied. Therefore, voids are evaluated on a basis of the location thereof. The location of a void is determined relative to a reference; a farthest side (terminal end) of a farthest one (terminal chip) of the power semiconductor chips 1 is assumed as the reference, the terminal chip being located farthest apart from the gate 20 and passed last by the sealing resin 10, the terminal end of the terminal chip being located farthest from the gate 20; and, of the voids 15, the location of a void closest to the terminal end is evaluated based on a distance L1 (hereinafter, “distance L1 between the chip and void”) between the terminal end of the terminal chip and a point of the void, closest to the terminal end (refer to FIG. 14).

As for criteria for conforming and not conforming, when the distance L1 between the chip and void is greater than 0.0 mm (void appears outside the terminal chip), the dielectric withstand voltage is satisfied and therefore, the device is regarded to conform; when the distance L1 is 0.0 mm or less (void appears above the terminal chip), the dielectric withstand voltage is not satisfied and therefore, the device is regarded to not conform. To further enhance the dielectric withstand voltage, preferably, the distance L1 between the chip and void may be greater than a distance L2 between the terminal side of the terminal chip and a farthest side of the stacked substrate 5, farthest from the gate 20. The distance L2 is, for example, 7.5 mm. Regarding use of SAT images and X-ray images, in terms of measuring principles thereof, the voids 15 above the stacked substrate 5 are not visible in the X-ray images while the voids 15 outside the stacked substrate 5 are not visible in the SAT images and therefore, confirming the presence/absence of voids and evaluating the location thereof is performed separately by transmission X-ray imaging only when the voids 15 are not present in the SAT images.

The impact that the voids 15 have on quality is evaluated by a dielectric breakdown test between the stacked substrate 5 and the external output terminals 12 of the front surface of the semiconductor device 50, and an upper limit of the voltage at which dielectric breakdown does not occur even when the voltage is applied for 60 seconds was obtained by increasing the voltage at 0.2 kV intervals. As for a criterium for conforming or not conforming, when the average of five withstand voltage measurements is 8.0 kV or greater, conforming is assumed.

FIG. 16 is a cross-sectional view depicting evaluation of voids behind the flow velocity control pins in the example. The voids 15 occurring behind the flow velocity control pins 14 are viewed in the SAT images obtained at a height (the observation surface 24) at which the circuit board 9 can be photographed by SAT performed with respect to a sample filled with the sealing resin 10 and the locations of the voids 15 are evaluated.

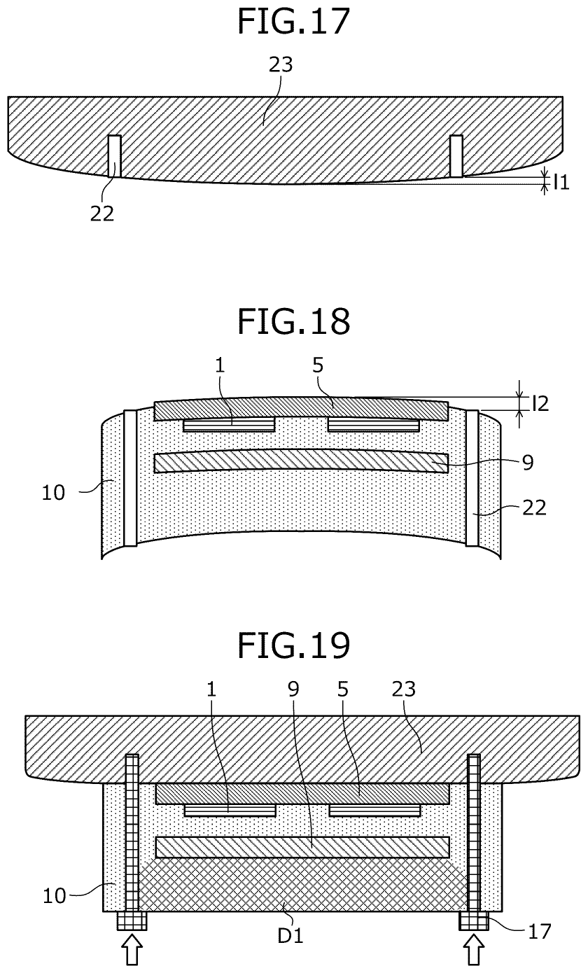

Strength testing of the module against deformation is implemented by a tightening test performed on a warped surface plate. FIG. 17 is a cross-sectional view depicting the warped surface plate of the tightening test in the example. A warped surface plate 23 is a surface plate in which a value of an initial warpage I1 between screw holes 22 variously wavers. The initial warpage I1 is a height of an apex from the screw holes 22 regarded as a reference. FIG. 18 is a cross-sectional view depicting warpage of the module in the example. Warpage I2 of the module is a height of an apex from the screw holes 22 regarded as a reference.

FIG. 19 is a cross-sectional view depicting the tightening test of the semiconductor device in the example. The tightening test is a test in which the module is tightly secured to the warped surface plate 23, thereby greatly deforming the module as compared to a flat surface plate and thus, generating tensile stress in the location D1 due to tightening of the screws. The test is a strength test in which the warped surface plate 23 is observed and sequentially replaced with ones having a relatively larger initial warpage I1 until cracking of the module is first observed.

As an index for evaluation, with a total amount of deformation obtained from a sum of the warpage I2 of the module+the initial warpage I1 between the screw holes 22 in the warped surface plate 23, the initial warpage I1 of the warped surface plate 23 was set in 20 μm increments between 0 μm and 300 μm, the screws were tightened having a torque of 3.5N·m and thereafter, whether cracking occurred in a center portion of the module after 10 seconds in this state was evaluated by visual inspection. The total amount of deformation when cracking occurred is the amount of deformation leading to cracking caused by tightening the screws.

The impact of deformation of the semiconductor device 50 on quality was evaluated by a power cycle (P/C) test. One cycle with conditions including a temperature range of 75 degrees C. to 150 degrees C. (ΔTvj 75 degrees C.), conduction operation for 1 second (current value is set so that 150 degrees is reached), and pausing operation for 9 seconds to 15 seconds (current value is set so that 75 degrees C. is reached) was assumed. The P/C lifetime was assumed to be the number of cycles until the current or the voltage fluctuates by 25% or more from a predetermined value. As for a criterium for conforming or not conforming, when the average of the number of destruction cycles for 5 devices is 1000 kcyc or greater, conforming is assumed.

In a first experimental example, the effect of the locations of the flow velocity control pins 14 was confirmed. Here, a sample free of the flow velocity control pins 14 (conventional structure) was fabricated as a comparison example 1, while samples having the flow velocity control pins 14 constituted by Ni/Cu pins in one of or a combination of the end portion A, the end portion B, and the intermediate region C were fabricated as examples 1-1, 1-2, 1-3, 1-4, 1-5, and 1-6, and the effects due to the locations of the flow velocity control pins 14 was evaluated. In the examples 1-1 to 1-6, the locations of the flow velocity control pins 14 were 1 mm away from the end of the circuit board 9 in the end portions A, B, and an intermediate location in a longitudinal direction of the circuit board 9, in the intermediate region C; and the height h of the flow velocity control pins 14 was assumed to be 1.65 mm while the distance L from the surface of the circuit board 9 to a product surface was assumed to be 2.5 mm (refer to FIGS. 1 and 3 regarding L, h). Further, with respect to the module width W (=26.0 mm), the flow velocity control pins 14 (n=22 pins) each having a circular column shape with a diameter d=0.4 mm are disposed on the circuit board 9, arranged at 0.5 mm intervals (refer to FIG. 3 regarding W, d). As a result, with respect to the cross-sectional area of the resin flow above the circuit board 9 (LW=2.5 mm×26.0 mm=65.0 mm²), the area projected by the flow velocity control pins 14 is “ndh=22×0.4 mm×1.65 mm=14.5 mm²” while a projection density (percentage of the area occupied by the pins) was “ndh/LW=14.5 mm²/65.0 mm²=22.3%”.

Results of the first experimental example are depicted in Table 1.

TABLE 1

| | | | | AMOUNT OF | |
|---|---|---|---|---|---|
| | | | | DEFORMATION | |
| | | DISTANCE | DIELECTRIC | WITH CRACKING | |
| EXAMPLE/ | | BETWEEN CHIP | BREAKDOWN | CAUSED BY | P/C |
| COMPARISON | PIN | AND VOID | VOLTAGE | TIGHTENING | LIFETIME |
| EXAMPLE | ARRANGEMENT | (mm) | (kV) | SCREWS (μm) | (kcyc) |
| COMPARISON | NONE | −0.75 | 7.6 | 200 | 900 |
| EXAMPLE 1 | (COMPARISON | | | | |
| | EXAMPLE) | | | | |
| EXAMPLE | ONLY A | 4.50 | 9.2 | 220 | 1000 |
| 1-1 | | | | | |
| EXAMPLE | ONLY B | 0.75 | 8.4 | 220 | 1000 |
| 1-2 | | | | | |
| EXAMPLE | ONLY C | 2.25 | 8.8 | 220 | 1000 |
| 1-3 | | | | | |
| EXAMPLE | A + B | 5.25 | 9.8 | 220 | 1000 |
| 1-4 | | | | | |
| EXAMPLE | A + C | 9.00 | 10.4 | 220 | 1000 |
| 1-5 | | | | | |
| EXAMPLE | A + B + C | NO VOIDS | 12.0 | 230 | 1100 |
| 1-6 | | | | | |

From Table 1, in the comparison example 1, it is found that the distance between the chip and void is in the negative direction, the dielectric breakdown voltage is low, and dielectric breakdown easily occurs. As described, in the comparison example 1 free of the flow velocity control pins 14, voids appear directly above the power semiconductor chips 1 and the dielectric breakdown tolerance does not reach the criteria for conforming.

On the other hand, in instances of all the examples 1-1 to 1-6, the distance between the chip and void is 0.0 mm or greater and the dielectric withstand voltage is 8 kV or greater and thus, all the examples 1-1 to 1-6 conform. An effect of controlling the location of voids for instances (the examples 1-1 to 1-3) in which the flow velocity control pins 14 are provided in only one region is exhibited by the following regions in descending order, the end portion A>the intermediate region C>the end portion B, and the closer the flow velocity control pins 14 are positioned to the gate 20 through which the resin flows in, the greater is an effect of reducing the velocity of the flow after the resin passes between the flow velocity control pins 14.

The effect of controlling the location of the voids in instances (the examples 1-4 to 1-6) in which the flow velocity control pins 14 are provided in a combination of two or more regions is exhibited by the following combinations, in descending order, A+B+C>A+C>A+B, and it was found that the greater is the number of regions where the flow velocity control pins 14 are provided, the higher is the effect and when the number of regions where the flow velocity control pins 14 are provided is the same, the effect is higher for instances in which the flow velocity control pins 14 are provided in a vicinity of the gate 20. In other words, preferably, the flow velocity control pins 14 may be disposed in regions that include the end portion A. In particular, the effect of controlling the location of the voids in an instances of A+B+C is significant and no void was even detected outside the stacked substrate 5. This was because the velocity of the flow of the resin was suitably controlled and moving the resin confluence position to a vicinity of the air vent 21 of the mold was successful, thereby enabling trapped air, which becomes voids, to be properly removed from the module. In all the examples excluding the example 1-6, it was confirmed that the sizes of the voids were about 300 μm, and while the location where voids appear may be controlled by the flow velocity control pins 14, the size of the voids cannot be reduced. Results of the dielectric breakdown test also exhibit the same trends as the trends exhibited by the distance between the chip and void, and it was confirmed that while the comparison example 1 was non-conforming, all the examples were conforming and the dielectric withstand voltage was enhanced. Further, from the tightening test and the P/C test, it was found that all the examples have an effect. This effect is presumed to be due to the rigidity of the module being enhanced by the flow velocity control pins 14 (metal), whereby an effect of suppressing deformation (reducing resin cracking) is achieved, thereby enhancing reliability (P/C lifetime).

In a second experimental example, an effect of the interval between the flow velocity control pins 14 was confirmed. In the second experimental example, the length (height) h and the number “n” of the flow velocity control pins 14 was varied, and an effect of adjusting the flow path within the cross-sectional area LW of the resin flow by the density ndh/LW projected by the flow velocity control pins 14 was evaluated. Samples were fabricated under the conditions including the length, the number, and the interval of the flow velocity control pins 14 depicted in Table 2, and similar to the first experimental example, Ni/Cu pins having a circular column shape with a diameter d=0.4 mm were used as the flow velocity control pins 14 and the flow velocity control pins 14 were provided only in the end portion A. Evaluation was performed on a basis of the distance between the chip and voids.

Results of the second experimental example are depicted in Table 2. In Table 2, similar to the first experimental example, “L” and “W” are the distance between the surface of the circuit board 9 and the product surface, and the width of the module, respectively. The length h of the pins is expressed with “L” as a reference.

TABLE 2

| PIN COUNT/ | | | | | | | |
|---|---|---|---|---|---|---|---|
| PIN INTERVAL | | 7 PINS/2.3 mm | | 13 PINS/1.2 mm | | 22 PINS/0.5 mm | |
| PIN COUNT | | 0.11 | | 0.20 | | 0.34 | |
| n × DIAMETER | | | | | | | |
| d + MODULE | | | | | | | |
| WIDTH W | | | | | | | |
| | | | DISTANCE | | DISTANCE | | DISTANCE |
| | | PROJECTION | BETWEEN | PROJECTION | BETWEEN | PROJECTION | BETWEEN |
| | | DENSITY | CHIP AND | DENSITY | CHIP AND | DENSITY | CHIP AND |
| | | ndh/LW | VOID | ndh/LW | VOID | ndh/LW | VOID |
| | | (%) | (mm) | (%) | (mm) | (%) | (mm) |
| PIN | 0.24 L | 2.6% | 0.25 | 4.8% | 0.25 | 8.1% | 0.50 |
| LENGTH h | 0.32 L | 3.4% | 0.25 | 6.4% | 0.50 | 10.8% | 1.25 |
| (mm) | 0.50 L | 5.4% | 0.50 | 10.0% | 1.50 | 16.9% | 4.25 |
| | 0.66 L | 7.1% | 0.25 | 13.2% | 1.50 | 22.3% | 4.50 |
| | 0.76 L | 8.2% | 0.50 | 15.2% | 3.50 | 25.7% | 4.75 |
| | 0.80 L | 8.6% | 0.75 | 16.0% | 3.25 | 27.1% | 6.50 |

| PIN COUNT/ | | | | | |
|---|---|---|---|---|---|
| PIN INTERVAL | | 33 PINS/0.2 mm | | 39 PINS/0.1 mm | |
| PIN COUNT | | 0.51 | | 0.60 | |
| n × DIAMETER | | | | | |
| d + MODULE | | | | | |
| WIDTH W | | | | | |
| | | | DISTANCE | | DISTANCE |
| | | PROJECTION | BETWEEN | PROJECTION | BETWEEN |
| | | DENSITY | CHIP AND | DENSITY | CHIP AND |
| | | ndh/LW | VOID | ndh/LW | VOID |
| | | (%) | (mm) | (%) | (mm) |
| PIN | 0.24 L | 12.2% | 2.50 | 14.4% | 2.75 |
| LENGTH h | 0.32 L | 16.2% | 3.25 | 19.2% | 4.50 |
| (mm) | 0.50 L | 25.4% | 5.50 | 30.0% | 7.25 |
| | 0.66 L | 33.5% | 8.00 | 39.6% | NO VOIDS |
| | 0.76 L | 38.6% | 8.25 | 45.6% | NO VOIDS |
| | 0.80 L | 40.6% | NO VOIDS | 48.0% | NO VOIDS* |

*MINOR COSMETIC DEFECTS

From Table 2, it was found that as the projection density ndh/LW by the flow velocity control pins 14 increases, the distance between the chip and void increases; the distance between the chip and void is +1 mm or greater when the projection density is 10% or greater; and the dielectric withstand voltage is also favorable. When the projection density is assumed to be 22% or greater, the distance between the chip and void is +4.5 mm or greater, which is particularly favorable. Further, when the projection density is 39.6% or greater, no voids are seen. Thus, it was found that the greater is the projection density by the flow velocity control pins 14, the greater is the effect of controlling the velocity of the flow of the resin. Nonetheless, when the projection density is 48% or greater, while a vicinity of the power semiconductor chips 1 was free of voids, the flow of the resin was excessively impeded by the flow velocity control pins 14, whereby in some instances, there were minor areas that were free of resin but did not interfere with practical use (cosmetic defects). Thus, preferably, the projection density may be 10% or greater, but less than 48% and more preferably, may be 22% or greater, and yet more preferably, may be 39.6% or greater, but less than 48%.

In a third experimental example, an effect of the material of the flow velocity control pins 14 was confirmed. In the third experimental example, confirmation was performed for an instance in which a resin having an elastic modulus lower than the elastic modulus of the sealing resin 10 was used as the material of the flow velocity control pins 14 (resin pins). The cured sealing resin 10 used in the first and second experimental examples was an epoxy resin (G720E manufactured by Sumitomo Bakelite Co., Ltd.) having a high Tg of 200 degrees C., the mold temperature during transfer sealing was 175 degrees C., and the elastic modulus after curing was about 16 GPa at 25 degrees C. In the third experimental example, an instance was evaluated in which an epoxy-type resin having a Tg of 200 degrees C. similar to the sealing resin 10 and for which the elastic modulus thereof was reduced to 6 GPa by removing a filler component from the composition was used as a material of the flow velocity control pins 14. The shape of the flow velocity control pins 14 was the same as the shape in the first and second experimental examples, a circular shape with a diameter of 0.4 mm; the density of the flow velocity control pins 14 was the same as the density in the first experimental example, 22 pins were fixed at a pin interval of 0.5 mm for a projection density of 22.3%.

Results of the third experimental example are depicted in Table 3.

TABLE 3

| | | | | | AMOUNT OF | |
|---|---|---|---|---|---|---|
| | | | | | DEFORMATION | |
| | | | | | WITH | |
| | | | DISTANCE | | CRACKING | |
| | | | BETWEEN | DIELECTRIC | CAUSED BY | |
| | | | CHIP AND | BREAKDOWN | TIGHTENING | P/C |
| | PIN | PIN | VOID | VOLTAGE | SCREWS | LIFETIME |
| | MATERIAL | ARRANGEMENT | (mm) | (kV) | (μm) | (kcyc) |
| COMPARISON | NONE | NONE | −0.75 | 7.6 | 200 | 900 |
| EXAMPLE 1 | | (COMPARISON | | | | |
| | | EXAMPLE) | | | | |
| EXAMPLE | Ni/Cu | ONLY A | 4.50 | 9.2 | 220 | 1000 |
| 1-1 | | | | | | |
| EXAMPLE | RESIN | ONLY A | 3.75 | 9.2 | 230 | 1100 |
| 3-1 | | | | | | |
| EXAMPLE | | ONLY B | 1.25 | 8.2 | 230 | 1100 |
| 3-2 | | | | | | |
| EXAMPLE | | ONLY C | 2.25 | 8.8 | 260 | 1200 |
| 3-3 | | | | | | |
| EXAMPLE | | A + B | 6.75 | 10.0 | 240 | 1100 |
| 3-4 | | | | | | |
| EXAMPLE | | A + C | 9.00 | 10.4 | 270 | 1250 |
| 3-5 | | | | | | |
| EXAMPLE | | A + B + C | NO VOIDS | 13.5 | 280 | 1400 |
| 3-6 | | | | | | |

From Table 3, it was found that the results of the dielectric breakdown test and the distance between the chip and void were nearly equal to the results of the dielectric breakdown test and the distance between the chip and void of the first experimental example. Therefore, it was found that the effect of adjusting the location of voids by the flow velocity control pins 14 is not altered by the material of the flow velocity control pins 14. On the other hand, in the results of the tightening test and the P/C test, improvement was seen as compared to the comparison example 1. This is thought to be due to a stress-mitigating effect obtained by disposing the resin pins having a low elastic modulus and easily stretched on the upper part of the module, where tensile stress concentrates due to tightening of the screws. In particular, when the resin pins that have a low elastic modulus are disposed in a center (the intermediate region C) of the module, where stress tends to concentrate (the examples 3-1 to 3-6), enhancement of the tolerance against destruction was significant. As compared to the example 1-1 and the example 3-1 in which the flow velocity control pins 14 were disposed only in the end portion A, enhancement of the P/C lifetime and the amount of deformation leading to cracking caused by tightening the screws was significant in the example 3-1 in which the resin pins were used. Thus, it may be said that while both the metal pins and the resin pins have an effect of reducing resin cracking, the resin pins have a greater effect.

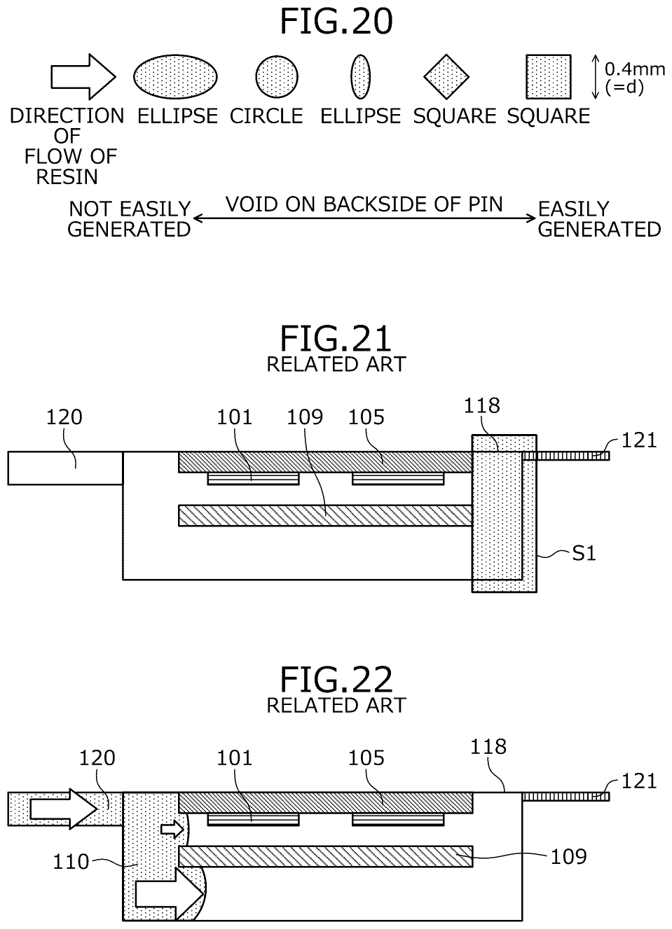

In a fourth example, in examples 4-1, 4-2, 4-3, and 4-4, an effect of the shape of the flow velocity control pins 14 was confirmed. Similar to the example 1-1, Ni/Cu pins were disposed in the end portion A, the flow velocity control pins 14 were prepared having shapes (shapes of cross-sections when viewed from upper surface) similar to the shapes in the first to third experimental examples and included columns with an elliptical shape and columns with a square shape in addition to columns with a circular shape. FIG. 20 is a cross-sectional view depicting the shapes of the flow velocity control pins of the semiconductor devices of the present example. The columns with a square shape (square columns) were provided for two instances, one in which one of the diagonals of the square shape was orthogonal to the direction of flow of the resin and one in which one side of the square shape was orthogonal to the direction of flow of the resin. The height h of the flow velocity control pins 14 was 1.65 mm and to set the projection density to 22.3%, the flow velocity control pins 14 of the sizes depicted in Table 4 were prepared so that the projection of the region orthogonal to the direction of flow of the resin was 0.4 mm. Both types of the elliptical columns had an oblateness of 50%. The columns with an elliptical shape (elliptical columns) were provided for two instances, one in which the minor axis was orthogonal to the direction of flow of the resin and one in which the major axis was orthogonal to the direction of flow of the resin.

Results of the fourth example are depicted in Table 4. In Table 4, “⊥” represents “orthogonal”. For example, “1 diagonal ⊥ to direction of flow of resin” is an instance in which one of the diagonals of the square shape is orthogonal the direction of flow of the resin.

TABLE 4

| | PIN SHAPE | | | | | |
|---|---|---|---|---|---|---|
| | (SHAPE OF | | SIZE d | DISTANCE | SIZE | |
| | CROSS-SECTION | | OF PIN | BETWEEN | OF VOID | DIELECTRIC |
| | WHEN VIEWED | | CROSS- | CHIP AND | BEHIND | BREAKDOWN |
| | FROM UPPER | | SECTION | VOID | PIN | VOLTAGE |
| | SURFACE | PIN ORIENTATION | (mm) | (mm) | (μm) | (kV) |
| COMPARISON | NONE | — | — | −0.75 | — | 7.6 |
| EXAMPLE 1 | (COMPARISON | | | | | |
| | EXAMPLE) | — | | | | |
| EXAMPLE 1-1 | CIRCULAR | | DIAMETER | 4.50 | <100 | 9.2 |
| | COLUMN | | 0.4 mm | | | |
| EXAMPLE 4-1 | ELLIPTICAL | MINOR AXIS ⊥ TO | MINOR AXIS | 5.00 | NO VOIDS | 9.6 |
| | COLUMN | DIRECTION OF | 0.4 mm | | | |
| | | RESIN FLOW | | | | |
| EXAMPLE 4-2 | ELLIPTICAL | MAJOR AXIS ⊥ TO | MAJOR AXIS | 4.25 | <100 | 9.2 |
| | COLUMN | DIRECTION OF | 0.4 mm | | | |
| | | RESIN FLOW | | | | |
| EXAMPLE 4-3 | SQUARE | 1 DIAGONAL ⊥ TO | DIAGONAL | 4.50 | 100~200 | 9.2 |
| | COLUMN | DIRECTION OF | 0.4 mm | | | |
| | | RESIN FLOW | | | | |
| EXAMPLE 4-4 | SQUARE | 1 SIDE ⊥ TO | 1 SIDE | 4.25 | 200~300 | 8.5 |
| | COLUMN | DIRECTION OF | 0.4 mm | | | |
| | | RESIN FLOW | | | | |

From Table 4, in all the examples, nearly equal distances between the chip and void were confirmed. As a result, it was found that an effect of controlling the velocity of the flow of the resin is constant and independent of the shape of the flow velocity control pins 14. Nonetheless, when the SAT image taken above the circuit board 9 was viewed, it was found that the voids 15 appeared behind the flow velocity control pins 14 (refer to FIG. 16). This is thought to be due to flow surfaces of the resin that has flowed past the flow velocity control pins 14 converging and entrapping air, whereby air pockets appeared behind the flow velocity control pins 14. The voids behind the flow velocity control pins 14 may compromise reliability and therefore, it is desirable for the voids to be small. The size of the voids behind the flow velocity control pins 14 varies depending on the shape and orientation of the flow velocity control pins 14 such that “circular columns·elliptical columns<square columns” is satisfied, where the elliptical columns (the minor axis ⊥ to the direction of flow of the resin) are the most favorable and the square columns (side ⊥ to the direction of flow of the resin) are the least favorable (refer to FIG. 17). While the breakdown voltage was generally correlated with the void size behind the flow velocity control pins 14, even when a void newly appeared behind the flow velocity control pins 14, the breakdown voltage improved as compared to the comparison example, and an effect of enhancing module performance independent of the shape of the flow velocity control pin 14 was confirmed.

In the foregoing, the present invention may be variously modified within a range not departing from the spirit of the invention and in the described embodiments, for example, dimensions, impurity concentrations, etc. of parts are variously set according to required specifications.

The semiconductor device and the method of manufacturing a semiconductor device according to the present invention achieve an effect in that the occurrence of voids in transfer molding may be reduced.

As described above, the semiconductor device and the method of manufacturing a semiconductor device according to the present invention are useful for power semiconductor modules used in power converting equipment of inverters, power source devices of various industrial machines, igniters of automobiles, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a stacked substrate;
a plurality of semiconductor chips provided on the stacked substrate;
an external output terminal;
a circuit board configured to electrically connect the plurality semiconductor chips, and to electrically connect the plurality of semiconductor chips to the external output terminal, the circuit board having a first surface and a second surface opposite to each other, the second surface facing the stacked substrate;
a sealing resin sealing the stacked substrate and the circuit board; and
a plurality of flow velocity control pins attached to the circuit board, at the first surface of the circuit board.

2. The semiconductor device according to claim 1, wherein
the circuit board has a first end and a second end opposite to each other, and
the plurality of flow velocity control pins is provided at the first end of the circuit board.

3. The semiconductor device according to claim 1, wherein
the circuit board has two opposite ends and an intermediate region between the two ends, and
the plurality of flow velocity control pins is provided both at the two ends of the circuit board and in the intermediate region.

4. The semiconductor device according to claim 1, wherein a material of the plurality of flow velocity control pins is a resin with an elastic modulus lower than an elastic modulus of the sealing resin.

5. A method of manufacturing a semiconductor device via transfer molding, the method comprising:
forming a module having
a stacked substrate on which a plurality of semiconductor chips is provided, and
a circuit board electrically connecting the plurality of semiconductor chips, and electrically connecting the plurality of semiconductor chips to an external output terminal, the circuit board having a first surface and a second surface opposite to each other, the second surface facing the stacked semiconductor substrate;
attaching the module to a mold having an injection gate;
injecting a sealing resin from the injection gate of the mold; and
disposing a plurality of flow velocity control pins, arranged orthogonal to a direction of a flow of the sealing resin, at the first surface of the circuit board.

6. The method according to claim 5, wherein
the circuit board has a first end and a second end opposite to each other, the first end facing the injection gate, and
the plurality of flow velocity control pins is disposed at the first end of the circuit board.

7. The method according to claim 5, wherein
the circuit board has a first end and a second end opposite to each other, the first end facing the injection gate, and
the plurality of flow velocity control pins is disposed at the first end and the second end of the circuit board.

8. The method according to claim 5, wherein
the circuit board has a first end and a second end opposite to each other, the first end facing the injection gate, and an intermediate region between the first end and the second end, and
the plurality of flow velocity control pins is provided at the first end, the second end, and in the intermediate region of the circuit board.

9. The method according to claim 5, wherein
the flow of the sealing resin is blocked by the plurality of flow velocity control pins, and
a projection density by which the flow is blocked by the plurality of flow velocity control pins is ndh/LW, which is no smaller than 10% and less than 48%, wherein
LW is an area of a cross-section of a path of the flow of the sealing resin, L being a distance from the first surface of the circuit board to a surface of the mold, W being a width of the mold in a direction orthogonal to the direction of the flow of the sealing resin, and
ndh is an area projected by the plurality of flow velocity control pins, n being a number of pins included in the plurality of flow velocity control pins, d being a width of each of the plurality of flow velocity control pins projected in the direction of the flow of the sealing resin, h being a height of each of the plurality of flow velocity control pins.

10. The method according to claim 5, wherein a material of the plurality of flow velocity control pins is a resin having an elastic modulus lower than an elastic modulus of the sealing resin.

11. The method according to claim 5, wherein a shape of a cross-section of each of the plurality of flow velocity control pins is an elliptical shape with a major axis oriented parallel to the direction of the flow of the sealing resin.
